(19) United States
(12) Patent Application Publication
(10) Pub. No.: US 2026/0353547 A1
(43) Pub. Date: Nov. 5, 2026

(54) IMPACT PROTECTION FOR ELECTRONICS IN LABELS

(71) Applicant: Powercast Corporation, Pittsburgh, PA (US)

(72) Inventors: Jeffrey D. WILL, Sarver, PA (US); Jason Arthur GILL, Pittsburgh, PA (US); Charles Edward GREENE, Butler, PA (US)

(21) Appl. No.: 19/196,427

(22) Filed: May 1, 2025

(51) Int. Cl. H05K 1/02; H05K 9/00

(52) U.S. Cl. CPC H05K 1/0218; H05K 1/025; H05K 9/0024; H05K 2201/0776; H05K 2201/10098; H05K 2201/10151

(57) ABSTRACT

In an embodiment, an apparatus includes a printed circuit board (PCB) that includes a plurality of electronic components. The plurality of electronic components includes a first electronic component, a second electronic component, and an antenna. The apparatus further includes a rigid sheet shielding at least a portion of the PCB. The rigid sheet exposes the first electronic component, and the rigid sheet does not expose the second electronic component. The rigid sheet includes a conductive material, and the rigid sheet affects a performance of the antenna by less than three decibels during operation of the antenna.

### FIELD

One or more embodiments relate to impact protections for electronics in shipping labels.

### BACKGROUND

Electronics can be damaged as they move around. Accordingly, protecting the electronics can be desirable. Where the electronics include an antenna, protecting the electronics while reducing (e.g., minimizing) undesirable impact of the antenna's performance can also be desirable.

### SUMMARY

In an embodiment, an apparatus includes a printed circuit board (PCB) that includes a plurality of electronic components. The plurality of electronic components includes a first electronic component, a second electronic component, and an antenna. The apparatus further includes a rigid sheet shielding at least a portion of the PCB. The rigid sheet exposes the first electronic component, and the rigid sheet does not expose the second electronic component. The rigid sheet includes a conductive material, and the rigid sheet affects a performance of the antenna by less than three decibels.

In an embodiment, an apparatus includes a printed circuit board (PCB) that includes a plurality of electronic components. The plurality of electronic components includes a first electronic component and a second electronic component. The apparatus further includes a rigid sheet configured to shield at least a portion of the PCB. The rigid sheet exposes the first electronic component, and the rigid sheet does not expose the second electronic component. The rigid sheet includes conductive material, and at least a portion of the rigid sheet functions as an antenna during operation of the plurality of electronic components.

In an embodiment, a printed circuit board (PCB) that includes a plurality of electronic components is received. The plurality of electronic components includes a first electronic component and a second electronic component. At least a portion of the PCB is shielded using a rigid sheet. The rigid sheet exposes the first electronic component, and the rigid sheet does not expose the second electronic component. The rigid sheet including conductive material.

### BRIEF DESCRIPTION OF THE DRAWINGS

FIG. 1 illustrates an exploded view of a stackup, according to an embodiment.

FIG. 2 illustrates a label affixed to a container containing an item, according to an embodiment.

FIG. 3 illustrates an exploded view of a stackup, according to an embodiment.

FIG. 4 illustrates a system block diagram of a package that includes a label, according to an embodiment.

### DETAILED DESCRIPTION

In some implementations, a label is configured to be affixed onto a package. The label includes a stackup of layers. The layers can include a layer(s) of electronics, such as a printed circuit board (PCB). To protect the electronics, the layers can also include a rigid sheet(s) (sometimes referred to herein as a “protective layer”) that shields at least a portion of at least some of the electronics from, for example, puncture, bending, or other mechanical effects. The electronics can also include an antenna, and the rigid sheet(s) can be configured to shield at least a portion of some of the electronics while having reduced (e.g., minimal) negative impact on the antenna's performance and/or improving the antenna's performance. In some implementations, shielding refers to physically shielding (e.g., a protective barrier that blocks, absorbs, or deflects external forces). For example, shielding an electronic component using a rigid sheet can refer to physically shielding the electronic component such that the rigid sheet can prevent (or at least mitigate) damage to the electronic component that would otherwise be caused by an external physical/mechanical forces.

In some implementations, a rigid sheet exposes/shields at least a portion of some electronic components at a PCB and does not expose/shield at least a portion of other electronic components at the PCB. An electronic component being exposed/shielded can refer to, for example, at least one side of the electronic component (not including the side opposite of where the rigid sheet is positioned) not being protected from external (e.g., environmental) effects via the rigid sheet (e.g., such that a light sensor can sense light at an environment of a package, such that a motion sensor can detect motion at an environment of the packet, etc.). In some implementations, exposure does not refer to visibility (e.g., an electronic component can be non-exposed by a rigid sheet even if the rigid sheet is transparent or semi-transparent). In some implementations, exposure of an electronic component refers to the electronic component being at risk of damage from an external physical effect (or at least more risk than an electronic component that is not exposed). In some implementations, an electronic component that is exposed or not exposed by the rigid sheet refers to physical exposure or non-exposure, respectively, and not electromagnetic interference (EMI). In some implementations, exposure of a sensor can refer to the sensor's sensing element being configured to actively interact with the environment the sensing element is designed to monitor, such as exposure to air for sensing applications such as temperature or humidity, exposure to environmental conditions such as liquids in the case of a water detection sensor, exposure light in the case of a light sensor, etc. In some implementations, non-exposure can refer to placing electronic components under the rigid sheet for force and impact protection (e.g., the rigid sheet is located between the electronic component and hazardous object), non-exposure to RF in the case of RF shielding, non-exposure to the environment in the case of high impact protection (IP) rated labels, etc. In some implementations, non-exposure to one element, such as impact, does not imply non-exposure to others, such as air; said differently, some implementations add impact protection to elements (e.g., electronic components) of the PCB while still allowing those elements access to, for example, air for humidity sensing via small holes.

For sensitive electronics, such as batteries, in a damage-prone industry like shipping, special mechanical protections can be desirable. For example, a punctured lithium battery on a shipping label could ignite a fire and cause significant harm to both equipment and personnel. To address this, some implementations incorporate a rigid sheet (e.g., spring steel sheet or other rigid material) within a label (e.g., laminated assembly). Positioned above, below, and/or adjacent to the electronics, this rigid sheet acts as an impact and puncture-resistant layer, providing a robust physical barrier between the electronics (e.g., the batteries) and external hazards. In some implementations, the electronics includes an antenna, and this protective layer can be incorporated with respect to the antenna to improve performance despite the protective layer including conductive material.

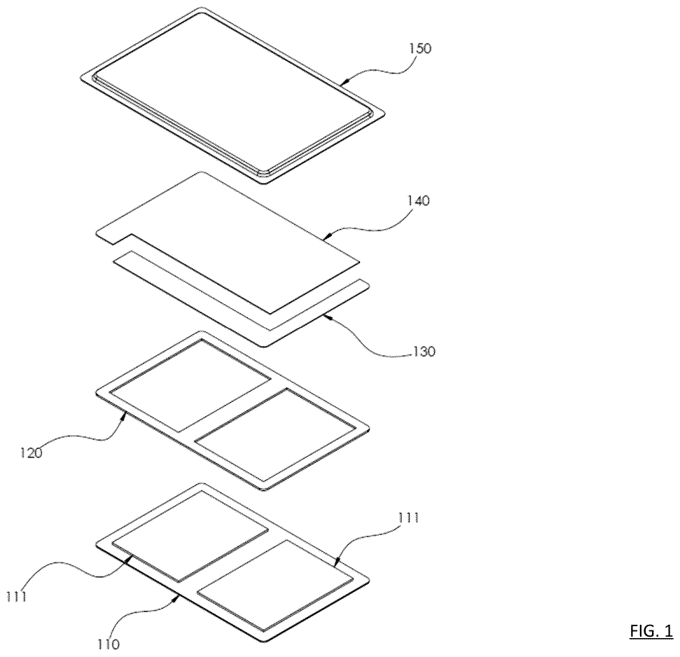

FIG. 1 illustrates an exploded view of a stackup, according to an embodiment. The stackup includes overlay 150, rigid sheet 140, dielectric 130, spacer 120, substrate 110, and circuitry 111. Circuitry 111 can be implemented on substrate 110. Circuitry 111 can include various electronic components, such as a battery, capacitor, resistor, inductor, antenna, and/or the like. Spacer 120 can be located above circuitry 111 and substrate 110 such that spacer 120 fits above substrate 110 and adjacent to circuitry 111. Rigid sheet 140 and dielectric 130 can be placed above circuitry 111 and spacer 120. Rigid sheet 140 and dielectric 130 can be disposed substantially within a common plane. Overlay 150 can be placed above rigid sheet 140 and dielectric 130. In some implementations, overlay 150 is formed using vacuum forming. In some implementations, overlay 150 is machined or injection modeled.

Adding protection to certain electronic devices to prevent damage to the internal electronics can be desirable. For devices that use a battery, such as a rechargeable lithium ion battery, the protection can be robust enough to prevent the battery from being bent, punctured, or otherwise negatively affected by environmental effects. Some implementations relate to ways in which the electronics may be protected and/or ways to use that protection in other areas to increase performance.

In a stackup, multiple different layers can be adhered together to produce the overall PCB layers of the label. This overall PCB layers can include different adhesives, spacers, overlays, and/or the like. To protect sensitive components, some implementations change the properties of an existing layer(s) in the stackup and/or add an additional layer(s) to the stackup. Examples of this include adding in a protective layer of spring steel (e.g., on one of the outer layers of the label) that covers some and/or all electronics that are sensitive to puncture and bending, while leaving room for/not covering electronics that are configured to operate under exposure (e.g., a light sensor, a motion sensor, a camera, etc.). In some implementations, other hard durable materials different than steel, such as certain plastics, wood, and/or other metals can be used as/included in the protective layer.

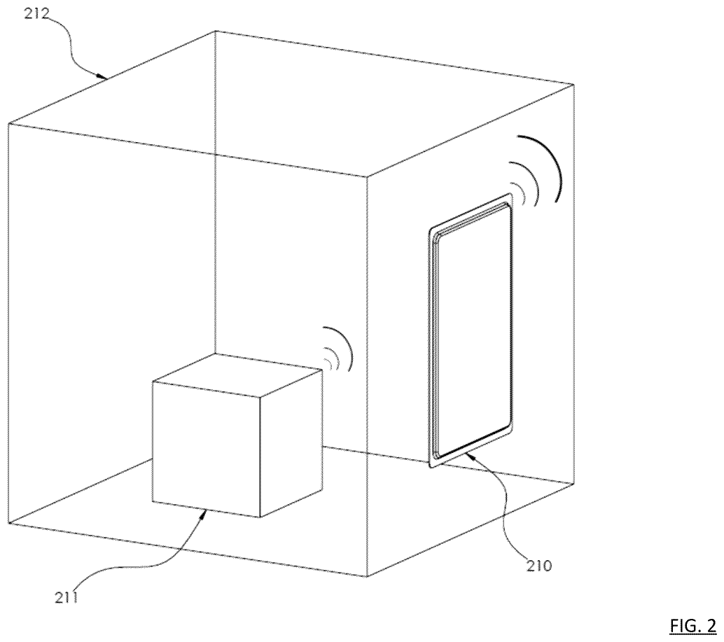

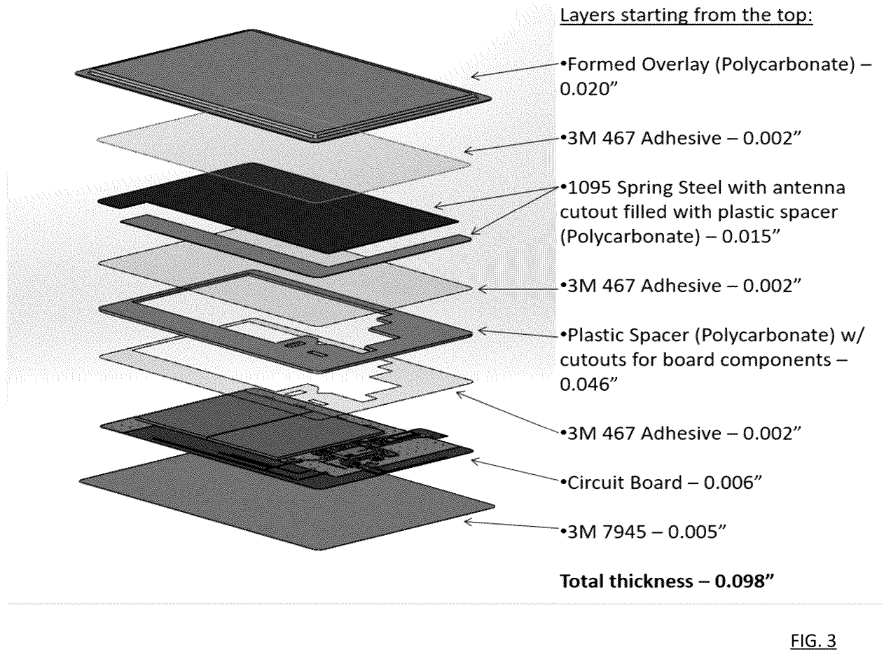

FIG. 2 illustrates a label affixed to a container containing an item, according to an embodiment. FIG. 2 includes container 212, item 211, and label 210. Container 212 can be any type of container, such as a plastic container, wood container, cardboard container, shipping container, crate, and/or the like. In some implementations, container 212 is not a metal container. Label 210 can be affixed to container 212 (e.g., via an adhesive, screwed in, etc.). Label 210 can have a stackup, such as the stackup illustrated at FIG. 1 and/or FIG. 3. Item 211 can be included in container 212. Item 211 can be, for example, an item that is to be shipped. Item 211 can be any type of item, such as food, apparel, pets, and/or the like. In some implementations, item 211 is within a smaller container (e.g., cardboard box), and multiples items (e.g., multiple items like item 211) are within a larger container (e.g., a larger cardboard box).

FIG. 3 illustrates an exploded view of a stackup, according to an embodiment. The stackup includes the following layers, from top to bottom: a formed overlay layer (e.g., made of polycarbonate); an adhesive layer (e.g., made of an adhesive such as 3M® 467); a rigid sheet layer (e.g., made of spring steel) and an antenna cutout filled with a plastic spacer (e.g., made of polycarbonate); an adhesive layer (e.g., made of an adhesive such as 3M® 467); a plastic spacer layer with cutouts for board components; an adhesive layer (e.g., made of an adhesive such as 3M® 467); a circuit board layer; and a membrane spacer (e.g., made of a polyester film and two adhesive layers, such as 3M® 7945).

In some implementations, the PCB itself is used as the protective layer. For this case, in some implementations, the material and/or thickness of the PCB substrate can be chosen to offer acceptable protection while reducing the effect on the performance of the electronics at the PCB. (e.g., an antenna included in the electronics at the PCB). For example, if the PCB includes electronics at a first side of the PCB, a second side of the PCB opposite from the first side can have a thickness that prevents the electronics from being punctured through the second side to the first side. The PCB substrate can also be chosen such that the material has a reduced (e.g., minimal) effect on the PCB performance but offers more protection, such as using an aluminum substrate. The PCB can also include or consist of multiple different substrates. For example, a first substrate can have components on one side and a copper layer on the second side and made of a PCB material such as FR4, while the second substrate can be made of a more protective material, such as aluminum and attached to the second side of the first substrate.

In some implementations, the stackup can include multiple protective layers that can but do not have to be of the same shape and/or size. Examples of this include using spring steel on both sides of the sensitive components to offer puncture and bend resistance on both sides, where the spring steels on each side can be the same shape and/or size or have a different shape and/or size. Additionally or alternatively, material can be added to the sides/walls of the electronics/PCB to further increase the protection level. Said differently, a PCB may include a first side (e.g., top), second side (e.g., bottom), and walls (e.g., sides) located between the first side and the second side, where the rigid sheet(s) can protect the first side, second side, and/or walls. Thus, in some instances, a given electronic component can be protected on all sides (e.g., top, bottom, and walls) or only some sides.

In some implementations, the stackup makes up the entirety of a label. The label can be used on (e.g., affixed to) containers (e.g., containers used in shipping) that does not inherently offer this protection itself (e.g., a cardboard box). For example, the label can be affixed to an outer surface of the container such that a user can view the label and/or read information printed on the label without opening or otherwise moving the container.

The protective layer can encompass the entire outer area of the label or can be designed to cover only a portion of the outer area of the label. Said differently, the protective layer can protect all electronics at the label or only a subset of electronics at the label. For the latter case, certain electronics, such as sensors configured to operate with access to the environment, inductive coils for charging or near field communication (NFC), antennas, and/or the like can remain uncovered by the protective layer, while still offering protection to the electronics that benefit from the protection; in other words, the electronics can be positioned in such a way that the electronics extend beyond or is visible through an opening in the protective layers, allowing the electronics to interact directly with its environment (without the potential impact of the protective layer(s)). The electronics to be protected from the protective layer(s) can include, for example, batteries (either primary or secondary) such as a lithium ion battery, lithium polymer battery, nickel metal hydride battery, solid state battery, alkaline battery, lead acid battery, and/or the like. Additionally or alternatively, other electronics to be protected can include, for example, capacitors, integrated circuits, sensors, inductors, wires, and/or the like.

In some implementations, the protective layer can be made of multiple differing types of materials to balance protection and electronic performance. In some implementations, different portions of the protective layer have differing thicknesses of the same material. For example, the protective layer can have a first thickness at a first region and a second thickness at a second region. In some implementations, the protective layer includes some areas of the protective layer made of a first material (e.g., metal, such as spring steel to increase protection), and other areas of the same layer being made of a second material (e.g., rigid plastic, to offer some protection while reducing the effect the first material can have on electronics, such as the antenna). In some implementations, some areas of the protective layer are permeable to gases and/or liquids to allow sensors in the label access to the gases/liquids while still offering protection.

Where the protective layer includes metal, this protective layer can be used as a capacitive and/or resistive touch plate for human interfacing with the label. An example of this could be registering (e.g., by a processor located at the PCB) each time a package is interacted with; these registrations can be used, for example, to study shipping efficiency.

In some implementations, the protective layer is used to track packages in the event of an external event that causes a loss of the shipping container. For example, an identifier of the label can be engraved onto the rigid sheet. By engraving directly into this layer of the label (e.g., during manufacturing), there will be a recoverable trackable portion of the label for later investigation. For example, if a fire burned a trailer of packages, the rigid sheet can remain and a user could associate the identifier etched into the rigid sheet to the contents of the package (e.g., similar to vehicle identification numbers (VINs) on cars and boats).

Certain electronics, such as an antenna, can be affected by the material in the protective layer. For example, metal at the protective layer could affect performance of the antenna. In this case, material can be selected to reduce (e.g., minimize) the effect of the protective layer on the antenna's performance and/or the antenna can be tuned/adapted to improve (e.g., maximize) performance when covered, fully or partially, by the protective layer. Additionally or alternatively, if a material such as a conductive material is to be used, the protective layer can be designed into the antenna to increase performance/mitigate undesirable performance. This can be accomplished by using the conductive material at the protective layer to increase the ground plane size and/or increase the effective aperture of the antenna. This conductive protective layer can be connected directly to the ground of the antenna or capacitively coupled to the ground. In some implementations, a spring steel is used at the rigid sheet to increase the effective size of the ground plane of the antenna and/or to increase the overall effective aperture size of the antenna to increase the antenna's gain.

In some implementations, a protective metal layer, such as spring steel, is used as the antenna. For example, a slot can be cut out of the conductive material of the protective metal layer to create a slot antenna. Thus, a processor at the PCB can receive and/or transmit signals via the antenna at the protective layer.

In some implementations, the protective layer includes multiple antennas at the same or different frequencies, polarizations, bandwidths, and/or the like. For example, multiple slots can be cut out at the protective layer to create different antennas (e.g., slot antennas, patch antennas, etc.). The protective metal allows different antennas to use different ground planes if desired and/or increase the size of the ground plane to increase the antenna's performance based on the frequencies, polarizations, bandwidths, and/or the like.

The PCB can also contain elements to reduce/negate the effects of the ground plane when the protective layer is not incorporated into the antenna design. For example, impedance matching circuitry (not shown) between the antenna and the PCB can be used. As another example, the PCB can also include a balun (not shown).

In some implementations, a stackup can include multiple metal layers. With the incorporation of multiple metallic layers, many different antennas designs can be created (produced, defined). An example is placing metal on the front and back to create a patch antenna or metal along the parameter to create (produce, define)a dipole antenna.

In some implementations, the label includes (e.g., at the PCB) global positioning system (GPS) circuitry (not shown). The GPS circuitry allows the real time location tracking of the label. Therefore, anything on which the label is placed (attached) can be geographically tracked.

In some implementations, the label includes (e.g., at the PCB), communication circuitry such as cellular (e.g., 3G, 4G, 5G, 6G, Category M (CATM), and/or the like), Wi-Fi®, Bluetooth® low energy (BLE), Zigbee®, Threads, Bluetooth® classic, 915 MHz and/or the like. The communication circuitry can be used to communicate with other compute devices. In some implementations, the communication circuitry can be used to supplement the GPS in terms of location tracking, for real time communication, to activate/deactivate other electronics on the label, for provisioning, to receive or send sensor information, and/or the like. Additionally or alternatively, through the communication circuitry, the label can act as a Digital Product Passport (DPP) and include information on the life cycle, origin, composition, and sustainability features, as well as recycling information of the label itself or the contents of what the label is affixed to.

In some implementations, the label includes sensors, such as a temperature sensor, light sensor, humidity sensor, shock sensor, and/or the like. The sensors can, for example, collect sensor data over the duration of the product the label is applied to. The sensor data can then be used to determine (e.g., by a processor and/or human) whether the product remained in compliance based on those sensor outputs and/or alert users if the device is in adverse environmental conditions (e.g., outside a predetermined acceptable temperature range, outside a predetermined acceptable humidity range, outside a predetermined acceptable vibration frequency range, outside a predetermined acceptable noise range, etc.).

In some implementations, the communication circuity and sensors are used to provide real time quality measurements to determine the health of the label and/or the product the label is affixed to. For example, if the label is attached to a perishable item or container containing a perishable item, sensor data can be collected and transmitted indicating whether the perishable item stayed within an acceptable temperature or humidity range.

In some implementations, the label is used as a gateway and communication device. Other devices separate from the label itself, having their own energy storage source and own sensors, can communicate with the label via Bluetooth® low energy (BLE), Bluetooth® classic, Zigbee®, Threads, Wi-Fi®, or other low power communication protocols. The label can then communicate the sensor information to a server (not shown) via, for example, cellular or Wi-Fi®. Thus, in some implementations, multiple sensors are added to same device to which the label is affixed, allowing different sensor types to be added in different locations. This also reduces (e.g., eliminates) the need to add the higher power communications, such as cellular or Wi-Fi®, to each sensor device, thereby cutting the power requirements of the separate peripheral devices and easing certification of those devices. Additionally, this cuts the cost of those peripheral devices, thereby allowing the label (which may be reusable and rechargeable) to contain the bulk of the expense and power draw.

In some implementations, the label includes (e.g., at the PCB) a rechargeable battery that is protected using techniques described herein. The battery can be recharged using, for example, wireless inductive charging, wireless magnetic resonance, wireless RF, USB A, USB B, USB C, direct DC, and/or the like.

In some implementations, the label act as a power source and/or the gateway to send power wirelessly to the separate sensor devices. The label can send power via RF, magnetic resonance, inductive, IR, and/or the like to power various sensors across the device to which the label is affixed. For this use case, in some implementations, the label is not designed using a stackup as mentioned above, but can be entirely encapsulated into an enclosure to add ruggedness and a high ingress protection (IP) rating.

In some implementations, the PCB includes electronic components and an energy storage device, such as a battery. The electronic components can include a wireless communication device and be configured with an antenna. The PCB can be part of a larger stackup that can include a spacer(s), adhesive(s), label(s), and/or the like. The stackup can also include a protections layer made of a rigid material, such as metal. The protective layer is configured to protect the electronic components and the energy storage device from puncture and/or bending. The protective layer can be configured with cut-outs and/or shaped such that the interference caused by the protective layer on the antenna is reduced (e.g., minimized), for example, such that the performance of the antenna is within 3 decibels (dBs) of a non-protected version that does not include the protective layer.

In some implementations, the cutout in the protective layer is filled with a controlled dielectric material, such as PCB material, ceramic, plastics, glass, and/or the like such that the effect the protective layer has on the antenna performance is further reduced (e.g., minimized). For example, a first region of the protective layer nearby an antenna can be made of a controlled dielectric material, and a second region of the protective layer nearby a battery can be made of metal.

In some implementations, the PCB includes an inverted-F antenna. If the PCB contains an inverted-F antenna (such that the antenna relies on part of the PCB ground plan to achieve resonance), adding the protective layer can effectively increase the ground plane and change the antenna performance.

Where an antenna is used, a protective layer might affect the antenna's performance. For example, dipole antennas are balanced antennas and can rely on symmetry of current on the negative and positive arms of the dipole; adding the conductive protective layer within the near field of the dipole antenna can detune the antennas. As another example, chip antennas are often characterized on a specific ground plane size, so adding the protective layer and changing the ground plane size can have adverse effects on chip antennas. Changes induced by adding the protective layer can also include changing the radiation pattern, shifting the fundamental frequency, or decreasing resonance. Further, a conductive material overtop of the radiative element of the antenna can detune the antenna. A frequency shift can also cause the operating frequency of the antenna to shift frequency away from the fundamental communication frequency of the communication protocol by more than the bandwidth of the communication channel. For example, for BLE, an antenna previously turned to the BLE band of 2.400-2.4835 GHz could have its the resonant frequency shifted out of the BLE band by a conductive material of the protective layer(s). As another example, cellular CAT-M and NB-IoT devices have operating bandwidths of 1.4 MHz and 180 kHz, respectively, so having a significant shift in operating frequency of the antenna could render communication at these frequencies inoperable. Changes in radiation pattern can also shift the gain of the antenna to other physical directions or lower the gain all together, which decreases the distance at which communication is possible.

One or more of the techniques described herein, however, can allow the protective layer to be incorporated into the antenna design with reduced (e.g., minimized) effects of the protective layer on the antenna. For unbalanced antennas that rely on the ground plane as part of the antenna, such as an inverted-F antenna, planar inverted-F antenna (PIFA), chip antenna, monopole antenna, spiral antenna, and/or the like, the protective layer can be designed to be within +/−10% of the size of the PCB ground plane, effectively “hiding” the protective layer from the antenna. As a result, in some implementations, the effect of the protective layer on antenna performance is +/−1 dB. Other techniques include using the protective layer as the ground plane, allowing the PCB to be smaller and having the PCB ground either electrically connected to the protective layer or capacitively coupled the protective layer; as a result, in some implementations, the effect of the protective layer on antenna performance is +/−1 dB.

In some implementations, where the protective layer covers the radiative element of the antenna, a different layer separates the antenna from the protective layer. A thickness and/or dielectric constant of the material is chosen for the layer such that the performance of the antenna not degraded below a predetermined acceptable value, such as 3 dB, 2 dB, or 1 dB. The full operating frequency of the communication protocol can be contained entirely within, for example, the −6 dB bandwidth of the antenna.

If the cutout of the protective layer around the antenna does not encompass the entire radiative portion of the antenna, the cutout size and location can be chosen such that the performance of the antenna is changed by no more than a predetermined acceptable value, such as 3 dB, 2 dB, or 1 dB. The full operating frequency of the communication protocol can be contained entirely within, for example, the −6 dB bandwidth of the antenna.

In some implementations, the antenna is configured to have a sufficiently wide bandwidth to allow environmental conditions, such as the material the label will be placed on, boxes or materials placed close to the antenna (e.g., within 1 wavelength), humidity or liquids on the label, and/or the like to have reduced (e.g., minimal) affect the performance of the antenna. In some implementations, the operating frequency range (e.g., the −6 dB bandwidth) of the label, when placed in an environment in which the label is intended to be used, will shift higher or lower in frequency. The antenna can be designed such that, even when this shift occurs, the operating frequency and bandwidth of the communication protocol is included in the operating range of the antenna.

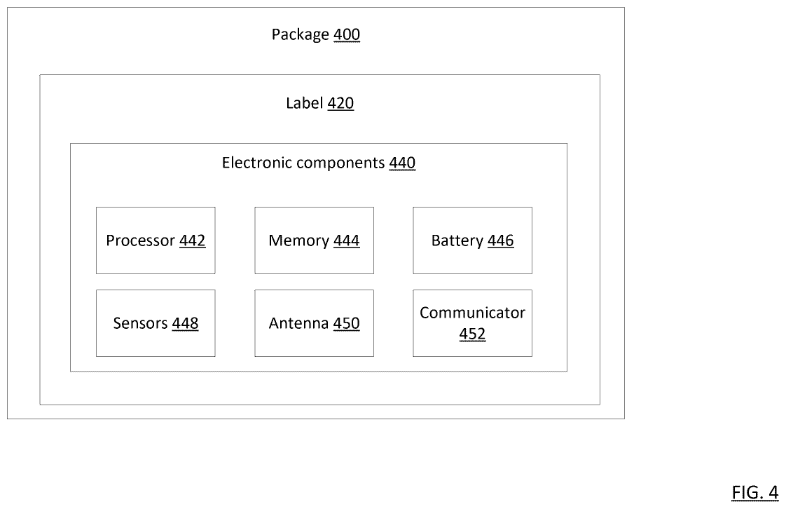

FIG. 4 illustrates a system block diagram of a package that includes a label, according to an embodiment. FIG. 4 illustrates package 400, label 420, and electronic components 440.

Package 400 can be any type of container configured to hold any type of item. Label 420 can be affixed to package 400 (e.g., using an adhesive). Label 420 can include various layers (e.g., as illustrated at FIGS. 1 and/or 3). Among various layers, label 420 can include electronic components 440. Electronic components 440 can include (e.g., at a PCB) processor 442, memory 444, battery 446, sensors 448, antenna 450, and communicator 452, each of which can be operatively coupled to each other (e.g., via a system bus).

Memory 444 can be, for example, a random-access memory (RAM), a memory buffer, a hard drive, a read-only memory (ROM), an erasable programmable read-only memory (EPROM), and/or the like. Memory 444 can be configured to store, for example, data. In some instances, memory 444 can store, for example, one or more software programs and/or code that can include instructions to cause processor 442 to perform one or more processes, functions, and/or the like. In some embodiments, memory 444 can include extendable storage units that can be added and used incrementally. In some implementations, memory 444 can be a portable memory (for example, a flash drive, a portable hard disk, and/or the like) that can be operatively coupled to processor 442.

Communicator 452 can be a hardware device operatively coupled to processor 442 and memory 444, and/or software stored in the memory 444 executed by the processor 442. Communicator 452 can be, for example, a network interface card (NIC), a Wi-Fi® module, a Bluetooth® module and/or any other suitable wired and/or wireless communication device. Furthermore, the communicator 452 can include a switch, a router, a hub and/or any other network device. In some instances, communicator 452 can be configured to connect to a communication network such as, for example, the Internet, an intranet, a local area network (LAN), a wide area network (WAN), a metropolitan area network (MAN), a worldwide interoperability for microwave access network (WiMAX®), an optical fiber (or fiber optic)-based network, a Bluetooth® network, a virtual network, and/or any combination thereof. In some instances, communicator 452 can facilitate receiving and/or transmitting data or files through a communication network. In some instances, received data and/or a received file can be processed by the processor 442 and/or stored in the memory 444.

Processor 442 can be, for example, a hardware based integrated circuit (IC) or any other suitable processing device configured to run and/or execute a set of instructions or code. For example, the processor 442 can be a general-purpose processor, a central processing unit (CPU), an accelerated processing unit (APU), an application specific integrated circuit (ASIC), a field programmable gate array (FPGA), a programmable logic array (PLA), a complex programmable logic device (CPLD), a programmable logic controller (PLC) and/or the like. The processor 442 can be operatively coupled to the memory 444 through a system bus (for example, address bus, data bus and/or control bus).

Battery 446 can be any type of battery. In some implementations, battery 446 is a rechargeable battery. Although not shown in FIG. 4, in some implementations, label 420 includes at least one rigid sheet that protects at least a portion of battery 446.

Sensors 448 can include any type of sensor. Sensor 448 can include, for example, a temperature sensor, a humidity sensor, a motion sensor, a vibration sensor, a camera, and/or the like. In some implementations, sensor 448 includes a first set of sensors that can generate accurate outputs despite being covered by a rigid sheet, and a second set of sensors that do not generate accurate outputs when covered by the rigid sheet. Thus, in some implementations, the second set of sensors are partially exposed; in other words, the second set of sensors are not fully surrounded by the rigid sheet.

Antenna 450 can be any type of antenna, such as a dipole antenna, patch antenna, slot antenna, phased array antenna, and/or the like. Antenna 450 can be configured to receive and/or transmit radio frequency (RF) signals for processor 442.

In an embodiment, an apparatus includes a printed circuit board (PCB) that includes a plurality of electronic components (e.g., electronic components 440). The plurality of electronic components can include a first electronic component, a second electronic component, and an antenna (e.g., antenna 450). A rigid sheet shields at least a portion of the PCB. The rigid sheet exposes the first electronic component, and the rigid sheet does not expose the second electronic component. The rigid sheet includes a conductive material, and the rigid sheet affects a performance of the antenna by less than three decibels during operation of the antenna.

In some implementations, the PCB includes a ground plane electrically connected to the rigid sheet. In some implementations, the PCB includes a ground plane and a size of the rigid sheet is (1) no more than 10% larger than a size of the ground plane and (2) no more than 10% smaller than the size of the ground plane. In some implementations, the PCB includes an impedance matching circuit, and the antenna electrically connected to the impedance matching circuit. In some implementations, a first portion of the rigid sheet includes a dielectric material, and a second portion of the rigid sheet does not include the dielectric material. In some implementations, the rigid sheet has a first portion with a thickness and a second portion with a thickness different than the thickness of the first portion. In some implementations, the second electronic component is at least one of a battery, a capacitor, a sensor, or an integrated circuit. In some implementations, the first electronic component is a sensor. In some implementations, the PCB includes a first side, a second side opposite the first side, and a wall disposed between the first side and the second side, and during operation of the plurality of electronic components, the rigid sheet shields at least a portion of the first side of the PCB, at least a portion of the second side of the PCB, and at least a portion of the wall of the PCB. In some implementations, the plurality of electronic components includes a processor, and the processor is configured to detect, based on at least one of a resistance or a capacitance of the rigid sheet, that the rigid sheet has been contacted. In some implementations, the rigid sheet further includes at least one of wood or plastic. In some implementations, the PCB includes a ground plane, a size of the rigid sheet is (1) no more than 10% larger than a size of the ground plane and (2) no more than 10% smaller than the size of the ground plane, and the antenna is at least one of an inverted-F antenna, a chip antenna, a monopole antenna, or a spiral antenna. Some implementations further include a dielectric layer located between the rigid sheet and the PCB.

In an embodiment, an apparatus includes a printed circuit board (PCB) that includes a plurality of electronic components. The plurality of electronic components includes a first electronic component and a second electronic component. The rigid sheet is configured to shield at least a portion of the PCB. The rigid sheet exposes the first electronic component, and the rigid sheet does not expose the second electronic component. The rigid sheet includes conductive material, and at least a portion of the rigid sheet functions as an antenna during operation of the plurality of electronic components.

In some implementations, the PCB includes an impedance matching circuit electrically connected to the portion of the rigid sheet. The rigid sheet includes a cutout filled with a dielectric material, the first electronic component is a sensor, and the second electronic component is at least one of a battery, a capacitor, a sensor, or an integrated circuit.

In an embodiment, a method includes receiving a printed circuit board (PCB) that includes a plurality of electronic components. The plurality of electronic components includes a first electronic component and a second electronic component. The method further includes shielding at least a portion of the PCB using a rigid sheet. The rigid sheet exposes the first electronic component, and the rigid sheet does not expose the second electronic component. The rigid sheet includes conductive material.

In some implementations, the PCB and the rigid sheet are coupled to a container configured to contain an object, and the object does not include a sensor. For example, a sensor is not attached to or located within the sensor. In some implementations, at least a portion of the rigid sheet (e.g., the entire rigid sheet, only a portion of the rigid sheet) is a radio frequency (RF) shield.

In some implementations, the PCB and the rigid sheet are coupled to a container configured to contain an object, the object includes a first sensor configured to communicate using a first communication protocol, and the plurality of electronic components include a second sensor configured to communicate using a second communication protocol different than the first communication protocol. Thus, if a circuitry (e.g., a remote compute device) is configured to communicate using the second communication protocol and not the first communication protocol, that circuitry can still receive data associated with the object via the second communication protocol.

In some implementations, the PCB and the rigid sheet are coupled to a container configured to contain an object, and the plurality of electronic components includes a processor and a sensor. The processor is configured to receive, after coupling the PCB and the rigid sheet to the container, sensor data from the sensor. The processor is further configured to determine a condition of at least one of the container or the object based on the sensor data. The processor is further configured to send a representation of at least one of the condition or the sensor data to a remote compute device. For example, the processor can receive an electronic signal representing the sensor data, determine a condition of the container or object (e.g., the container is damaged, the object was exposed to high heat, etc.), and send an electronic signal representing the determined condition to the remote compute device (using communicator 452).

Combinations of the foregoing concepts and additional concepts discussed here (provided such concepts are not mutually inconsistent) are contemplated as being part of the subject matter disclosed herein. The terminology explicitly employed herein that also may appear in any disclosure incorporated by reference should be accorded a meaning most consistent with the particular concepts disclosed herein.

The skilled artisan will understand that the drawings primarily are for illustrative purposes, and are not intended to limit the scope of the subject matter described herein. The drawings are not necessarily to scale; in some instances, various aspects of the subject matter disclosed herein may be shown exaggerated or enlarged in the drawings to facilitate an understanding of different features. In the drawings, like reference characters generally refer to like features (e.g., functionally similar and/or structurally similar elements).

To address various issues and advance the art, the entirety of this application (including the Cover Page, Title, Headings, Background, Summary, Brief Description of the Drawings, Detailed Description, Embodiments, Abstract, Figures, Appendices, and otherwise) shows, by way of illustration, various embodiments in which the embodiments may be practiced. As such, all examples and/or embodiments are deemed to be non-limiting throughout this disclosure.

It is to be understood that the logical and/or topological structure of any combination of any program components (a component collection), other components and/or any present feature sets as described in the Figures and/or throughout are not limited to a fixed operating order and/or arrangement, but rather, any disclosed order is an example and all equivalents, regardless of order, are contemplated by the disclosure.

Various concepts may be embodied as one or more methods, of which at least one example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments. Put differently, it is to be understood that such features may not necessarily be limited to a particular order of execution, but rather, any number of threads, processes, services, servers, and/or the like that may execute serially, asynchronously, concurrently, in parallel, simultaneously, synchronously, and/or the like in a manner consistent with the disclosure. As such, some of these features may be mutually contradictory, in that they cannot be simultaneously present in a single embodiment. Similarly, some features are applicable to one aspect of the innovations, and inapplicable to others.

The indefinite articles “a” and “an,” as used herein in the specification and in the embodiments, unless clearly indicated to the contrary, should be understood to mean “at least one.”

The phrase “and/or,” as used herein in the specification and in the embodiments, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the embodiments, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the embodiments, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of.” “Consisting essentially of,” when used in the embodiments, shall have its ordinary meaning as used in the field of patent law.

As used herein in the specification and in the embodiments, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the embodiments, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

Some embodiments described herein relate to a computer storage product with a non-transitory computer-readable medium (also can be referred to as a non-transitory processor-readable medium) having instructions or computer code thereon for performing various computer-implemented operations. The computer-readable medium (or processor-readable medium) is non-transitory in the sense that it does not include transitory propagating signals per se (e.g., a propagating electromagnetic wave carrying information on a transmission medium such as space or a cable). The media and computer code (also can be referred to as code) may be those designed and constructed for the specific purpose or purposes. Examples of non-transitory computer-readable media include, but are not limited to, magnetic storage media such as hard disks, floppy disks, and magnetic tape; optical storage media such as Compact Disc/Digital Video Discs (CD/DVDs), Compact Disc-Read Only Memories (CD-ROMs), and holographic devices; magneto-optical storage media such as optical disks; carrier wave signal processing modules; and hardware devices that are specially configured to store and execute program code, such as Application-Specific Integrated Circuits (ASICs), Programmable Logic Devices (PLDs), Read-Only Memory (ROM) and Random-Access Memory (RAM) devices. Other embodiments described herein relate to a computer program product, which can include, for example, the instructions and/or computer code discussed herein.

Some embodiments and/or methods described herein can be performed by software (executed on hardware), hardware, or a combination thereof. Hardware modules may include, for example, a processor, a field programmable gate array (FPGA), and/or an application specific integrated circuit (ASIC). Software modules (executed on hardware) can include instructions stored in a memory that is operably coupled to a processor, and can be expressed in a variety of software languages (e.g., computer code), including C, C++, Java™, Ruby, Visual Basic™, and/or other object-oriented, procedural, or other programming language and development tools. Examples of computer code include, but are not limited to, micro-code or micro-instructions, machine instructions, such as produced by a compiler, code used to produce a web service, and files containing higher-level instructions that are executed by a computer using an interpreter.

For example, embodiments may be implemented using imperative programming languages (e.g., C, Fortran, etc.), functional programming languages (Haskell, Erlang, etc.), logical programming languages (e.g., Prolog), object-oriented programming languages (e.g., Java, C++, etc.) or other suitable programming languages and/or development tools. Additional examples of computer code include, but are not limited to, control signals, encrypted code, and compressed code.

The terms “instructions” and “code” should be interpreted broadly to include any type of computer-readable statement(s). For example, the terms “instructions” and “code” may refer to one or more programs, routines, sub-routines, functions, procedures, etc. “Instructions” and “code” may include a single computer-readable statement or many computer-readable statements.

While specific embodiments of the present disclosure have been outlined above, many alternatives, modifications, and variations will be apparent to those skilled in the art. Accordingly, the embodiments set forth herein are intended to be illustrative, not limiting.

What is claimed is:

1. An apparatus, comprising:
a printed circuit board (PCB) that includes a plurality of electronic components, the plurality of electronic components including a first electronic component, a second electronic component, and an antenna; and
a rigid sheet shielding at least a portion of the PCB, the rigid sheet exposing the first electronic component, the rigid sheet not exposing the second electronic component, the rigid sheet including a conductive material, the rigid sheet affecting a performance of the antenna by less than three decibels during operation of the antenna.

2. The apparatus of claim 1, wherein the PCB includes a ground plane electrically connected to the rigid sheet.

3. The apparatus of claim 1, wherein the PCB includes a ground plane and a size of the rigid sheet is (1) no more than 10% larger than a size of the ground plane and (2) no more than 10% smaller than the size of the ground plane.

4. The apparatus of claim 1, wherein the PCB includes an impedance matching circuit, the antenna electrically connected to the impedance matching circuit.

5. The apparatus of claim 1, wherein a first portion of the rigid sheet includes a dielectric material, and a second portion of the rigid sheet does not include the dielectric material.

6. The apparatus of claim 1, wherein the rigid sheet has a first portion with a thickness and a second portion with a thickness different than the thickness of the first portion.

7. The apparatus of claim 1, wherein the second electronic component is at least one of a battery, a capacitor, a sensor, or an integrated circuit.

8. The apparatus of claim 1, wherein the first electronic component is a sensor.

9. The apparatus of claim 1, wherein:
the PCB includes a first side, a second side opposite the first side, and a wall disposed between the first side and the second side, and
during operation of the plurality of electronic components, the rigid sheet shields at least a portion of the first side of the PCB, at least a portion of the second side of the PCB, and at least a portion of the wall of the PCB.

10. The apparatus of claim 1, wherein the plurality of electronic components includes a processor, the processor configured to:
detect, based on at least one of a resistance or a capacitance of the rigid sheet, that the rigid sheet has been contacted.

11. The apparatus of claim 1, wherein the rigid sheet further includes at least one of wood or plastic.

12. The apparatus of claim 1, wherein the PCB includes a ground plane, a size of the rigid sheet is (1) no more than 10% larger than a size of the ground plane and (2) no more than 10% smaller than the size of the ground plane, and the antenna is at least one of an inverted-F antenna, a chip antenna, a monopole antenna, or a spiral antenna.

13. The apparatus of claim 1, further comprising:
a dielectric layer located between the rigid sheet and the PCB.

14. An apparatus, comprising:
a printed circuit board (PCB) that includes a plurality of electronic components, the plurality of electronic components including a first electronic component and a second electronic component; and
a rigid sheet configured to shield at least a portion of the PCB, the rigid sheet exposing the first electronic component, the rigid sheet not exposing the second electronic component, the rigid sheet including conductive material, at least a portion of the rigid sheet functioning as an antenna during operation of the plurality of electronic components.

15. The apparatus of claim 14, wherein:
the PCB includes an impedance matching circuit electrically connected to the portion of the rigid sheet,
the rigid sheet includes a cutout filled with a dielectric material,
the first electronic component is a sensor, and
the second electronic component is at least one of a battery, a capacitor, a sensor, or an integrated circuit.

16. A method, comprising:
receiving a printed circuit board (PCB) that includes a plurality of electronic components, the plurality of electronic components including a first electronic component and a second electronic component; and
shielding at least a portion of the PCB using a rigid sheet, the rigid sheet exposing the first electronic component, the rigid sheet not exposing the second electronic component, the rigid sheet including conductive material.

17. The method of claim 16, wherein the PCB and the rigid sheet are coupled to a container configured to contain an object, and the object does not include a sensor.

18. The method of claim 16, wherein the PCB and the rigid sheet are coupled to a container configured to contain an object, the object includes a first sensor configured to communicate using a first communication protocol, and the plurality of electronic components include a second sensor configured to communicate using a second communication protocol different than the first communication protocol.

19. The method of claim 16, wherein the PCB and the rigid sheet are coupled to a container configured to contain an object, and the plurality of electronic components includes a processor and a sensor, the processor configured to:
receive, after coupling the PCB and the rigid sheet to the container, sensor data from the sensor;
determine a condition of at least one of the container or the object based on the sensor data; and
send a representation of at least one of the condition or the sensor data to a remote compute device.

20. The method of claim 16, wherein at least a portion of the rigid sheet is a radio frequency (RF) shield.
